(19) United States
(12) Patent Application Publication
(10) Pub. No.: US 2025/0106991 A1
(43) Pub. Date: Mar. 27, 2025

(54) CIRCUIT BOARD AND METHOD OF FABRICATING CIRCUIT BOARD

(71) Applicant: SAMSUNG ELECTRO-MECHANICS CO., LTD., Suwon-si (KR)

(72) Inventors: Seong Ho Choi, Suwon-si (KR); Jun Ki Min, Suwon-si, Gyeonggi-do (KR)

(73) Assignee: SAMSUNG ELECTRO-MECHANICS CO., LTD., Suwon-si (KR)

(21) Appl. No.: 18/585,618

(22) Filed: Feb. 23, 2024

(30) Foreign Application Priority Data
Sep. 27, 2023 (KR) 10-2023-0130592

(51) Int. Cl. H05K 1/02

(52) U.S. Cl. CPC H05K 1/0298; H05K 2201/10734; H05K 2201/2081

(57) ABSTRACT

A disclosed circuit board includes: a first insulating layer that has a first surface and a second surface opposing each other; a first wire layer that is buried within the first insulating layer; and a bump that includes a base portion disposed laterally to the first wire layer to be buried within the first insulating layer and a protrusion portion integrally extending and protruding from the base portion and having a width at an upper end thereof less than a width of the protrusion portion at a height of the first surface.

### CROSS-REFERENCE TO RELATED APPLICATION

This application claims priority to and the benefit of Korean Patent Application No. 10-2023-0130592 filed at the Korean Intellectual Property Office on Sep. 27, 2023, the entire contents of which are incorporated herein by reference.

### TECHNICAL FIELD

The present disclosure relates to a circuit board and a method of fabricating the circuit board.

### BACKGROUND

Currently, a Ball Grid Array (BGA) board for a premium AP needs to have a smaller ball pitch as the number of I/O pins increases. To implement the fine ball pitch, a method of bonding a chip and the board may be changed from a method of using a solder bump to a method of using a copper bump.

If the copper bump is used, a bonding method between the board and the chip may be simply implemented even when there is a fine bump-to-bump interval, and an alignment technology between a circuit and the copper bump is not required. Because the change from the method of using the solder bump to the method of using the copper bump may effectively respond to the smaller ball pitch, a finer and more precise process of the copper bump is required.

### SUMMARY

One aspect of an embodiment is to provide a circuit board and a method of fabricating the circuit board that may precisely implement a fine pitch metal bump.

However, problems to be solved by embodiments of the present disclosure are not limited to the above-described problem and may be variously extended in a range of technical ideas included in the present disclosure.

A circuit board according to an embodiment includes: a first insulating layer that has a first surface and a second surface opposing each other; a first wire layer that is buried within the first insulating layer; and a bump that includes a base portion disposed laterally to the first wire layer to be buried within the first insulating layer and a protrusion portion integrally extending and protruding from the base portion and having a width of the protrusion portion at an upper end thereof less than a width at a height of the first surface.

In the protrusion portion, the width at the height of the first surface may be the largest and a width at the upper end of the protrusion portion may be the smallest.

The width of the protrusion portion may increase in a direction away from the first surface.

In a height measured in a direction perpendicular to the first surface, the base portion and the first wire layer may have portions disposed at the same height as each other.

The base portion and the protrusion portion may have the same width at the height of the first surface.

The circuit board may further include a first solder resist layer disposed on the first surface and configured to cover the first wire layer.

The bump may be disposed to penetrate the first solder resist layer.

The bump may protrude from the first solder resist layer.

The protrusion portion may be disposed to contact the first solder resist layer.

The first solder resist layer may be disposed to surround a portion of a side surface of the protrusion portion.

The bump may include copper (Cu).

The circuit board may further include a build-up structure disposed on the second surface of the first insulating layer and including a plurality of build-up insulating layers and a plurality of build-up wire layers.

The circuit board may further include a second solder resist layer disposed on an outermost insulating layer disposed at an outermost side of the plurality of build-up insulating layers.

A method of fabricating the circuit board according to an embodiment includes: forming a conductive layer including a second metal on a seed layer including a first metal; forming a bump layer on the seed layer exposed by patterning the conductive layer; forming an insulating layer and a wire layer above the conductive layer; removing the seed layer to form a bump from the bump layer; removing the conductive layer to protrude the bump from the insulating layer; and forming a solder resist layer on one surface of the insulating layer where the bump protrudes.

The first metal may include copper (Cu) and the second metal may include nickel (Ni).

The forming of the bump layer may include: applying a plating resist on the conductive layer and patterning the applied plating resist to expose the conductive layer; removing the exposed portion of the conductive layer to expose the seed layer; and forming the bump layer by plating the first metal on the exposed seed layer.

The bump may be formed to have the largest width at a surface height of the insulating layer and the smallest width at an outermost upper end thereof along a direction protruding from the insulating layer.

The method may further include forming a build-up structure on another surface of the insulating layer. The build-up structure may include a plurality of build-up insulating layers and a plurality of build-up wire layers.

The conductive layer and the seed layer may be formed on an insulating board which is removed after forming the build-up structure.

According to the method of fabricating the circuit board according to the embodiment, it is possible to precisely implement a fine pitch metal bump by preventing misalignment between the metal bump (a post) and a wire.

Therefore, according to the circuit board according to the embodiment, the board and a chip may be simply bonded by providing the fine pitch metal bump.

### BRIEF DESCRIPTION OF THE DRAWINGS

FIG. 1 is a cross-sectional view illustrating a circuit board according to an embodiment.

FIGS. 2 to 14 are process cross-sectional views illustrating a method of fabricating the circuit board shown in FIG. 1.

### DETAILED DESCRIPTION OF THE EMBODIMENTS

The present disclosure will be described more fully hereinafter with reference to the accompanying drawings, in which embodiments of the disclosure are shown. The drawings and description are to be regarded as illustrative in nature and not restrictive. Like reference numerals designate like elements throughout the specification. In the drawings, size and thickness of each element are arbitrarily illustrated for convenience of description, and the present disclosure is not necessarily limited to as illustrated in the drawings.

In addition, the attached drawing is only for easy understanding of the embodiment disclosed in the present specification, and the technical idea disclosed in this specification is not limited by the attached drawing, and all changes included in the spirit and technical range of the present disclosure, should be understood to include equivalents or substitutes.

Terms including an ordinal number such as first, second, and the like may be used to describe various configurations elements, but the constituent elements are not limited by the terms. The terms are used only for the purpose of distinguishing one constituent element from another.

It will be understood that when an element such as a layer, film, region, or substrate is referred to as being “on” or “above” another element, it may be directly on the other element or intervening elements may also be present. In contrast, when an element is referred to as being “directly on” another element, there are no intervening elements present. Further, throughout the specification, the word “on” or “above” a target element will be understood to be disposed above or below the target element, and will not necessarily be understood to be disposed “at an upper side” based on an opposite to gravity direction.

In the present application, terms such as “comprise” or “have” are intended to designate that a feature, number, step, operation, constituent element, part, or combination thereof described in the specification exists, and it should be understood as not precluding the possibility of the presence or addition of and one or more other features, numbers, steps, actions, constituent elements, parts, or combinations thereof. In addition, unless explicitly described to the contrary, the word “comprise” and variations such as “comprises” or “comprising” will be understood to imply the inclusion of stated elements but not the exclusion of any other elements.

Further, throughout the specification, the phrase “on a plane” means viewing a target portion from the top, and the phrase “on a cross-section” means viewing a cross-section formed by perpendicularly cutting a target portion from the side.

In addition, throughout the specification, “connected” does not mean only when two or more constituent elements are directly connected, but also when two or more constituent elements are indirectly connected through another constituent element, or when physically connected or electrically connected, and it may include a case in which substantially integral parts are connected to each other although they are referred to by different names according to positions or functions.

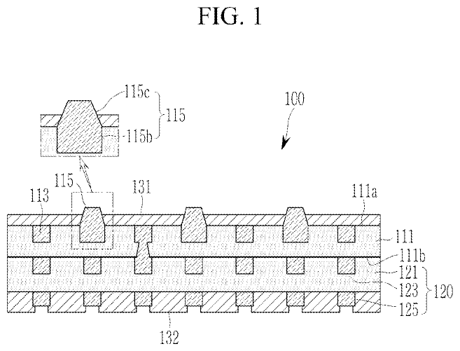

FIG. 1 is a cross-sectional view illustrating a circuit board according to an embodiment.

Referring to FIG. 1, the circuit board 100 according to the present embodiment includes a first insulating layer 111 and a first wire layer 113 buried within the first insulating layer 111. The first wire layer 113 and the first insulating layer 111 may constitute an embedded trace substrate (ETS) structure. The circuit board 100 may be a printed circuit board that may be used for a semiconductor package.

The first insulating layer 111 may have a first surface 111a and a second surface 111b opposing each other. A bump 115 may protrude above the first surface 111a of the first insulating layer 111. The bump 115 includes a base portion 115b buried within the first insulating layer 111, and a protrusion portion 115c integrally extending from the base portion 115b to protrude above the first surface 111a. The base portion 115b may be disposed laterally to the first wire layer 113 to be buried in the first insulating layer 111. The base portion 115b may be adjacent to the first wire layer 113. Therefore, in a height measured in a direction perpendicular to the first surface 111a, the base portion 115b may have a portion disposed at the same height as that of the first wire layer 113. The protrusion portion 115c may have the largest width at a height of the first surface 111a, and may have the smallest width at an outermost upper end thereof. For example, the protrusion portion 115c may gradually become thinner along a direction protruding from the first surface 111a. Here, the widths of the protrusion portion 115c may be compared to each other based on a width measured in a direction parallel to the first surface 111a in a cross-section of the protrusion portion 115c. The bump 115 may be formed in a post shape by the base portion 115b and the protrusion portion 115c that are integrally connected, and may include copper (Cu).

The first wire layer 113 may not protrude above the first insulating layer 111, and may constitute a circuit wire for signal transfer, power supply, a ground, and the like within the first insulating layer 111. The bump 115 may be exposed above the first insulating layer 111 through the protrusion portion 115c to be connected to terminals of an electronic element (not shown) such as an IC chip or the like.

The first insulating layer 111 may include a resin insulating layer. The first insulating layer 111 may be a thermosetting resin such as an epoxy resin, a thermoplastic resin such as polyimide, or a resin (for example, a prepreg) impregnated with a reinforcing material such as a glass fiber or an inorganic filler. Additionally, the first insulating layer 111 may include a thermosetting resin and/or a photo-curing resin, but the present disclosure is not limited thereto.

A width, a diameter, or a cross-sectional area of the protrusion portion 115c of the bump 115 may gradually decrease along the direction protruding from the first surface 111a. The direction protruding from the first surface 111a may be the same direction as a thickness direction of the first insulating layer 111. That is, the protrusion portion 115c may have a trapezoid-shaped cross-section having a narrow top and a wide bottom based on the first surface 111a. Therefore, a width, a diameter, or a cross-sectional area of the bump 115 may gradually decrease along the thickness direction of the first insulating layer 111.

The protrusion portion 115c may have the same width as that of the base portion 115b buried in the first insulating layer 111 at the height of the first surface 111a. The widths of the protrusion portion 115c and the base portion 115b may be measured in a direction parallel to the first surface 111a of the first insulating layer 111. Therefore, the protrusion portion 115c may have a width that gradually decreases from the base portion 115b at the height of the first surface 111a, and may protrude above the first surface 111a.

A first solder resist layer 131 may be disposed on the first surface 111a of the first insulating layer 111. The first solder resist layer 131 may be configured to cover the first wire layer 113. The bump 115 may be disposed to penetrate the first solder resist layer 131. In this case, the protrusion portion 115c may be disposed to contact the first solder resist layer 131. Additionally, a portion of a side surface of the protrusion portion 115c may be surrounded by the first solder resist layer 131.

A build-up structure 120 may be disposed on the second surface 111b of the first insulating layer 111. The build-up structure 120 may include a build-up insulating layer and a build-up wire layer. The build-up insulating layer may include a plurality of insulating layers 121, and the build-up wire layer may include a plurality of wire layers 123 and 125 buried in or disposed on each of the plurality of insulating layers.

The outermost wire layer 125 may be disposed on the outermost insulating layer 121 of the build-up structure 120 disposed at a side facing the first surface 111a of the first insulating layer 111. The outermost insulating layer 121 may be covered with a second solder resist layer 132, and at least a portion of the outermost wire layer 125 may be exposed by an opening of the second solder resist layer 132. The exposed outermost wire layer 125 may function as a pad for connection with another external component.

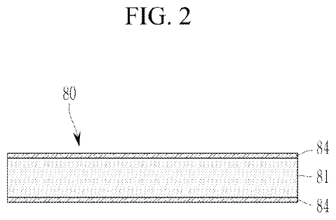

FIGS. 2 to 14 are process cross-sectional views illustrating a method of fabricating the circuit board shown in FIG. 1. The method of fabricating the circuit board will be described with reference to FIGS. 1 and 2 to 14.

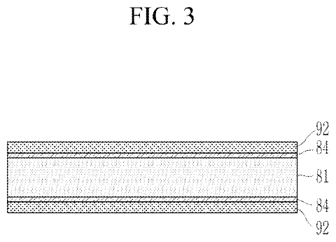

Referring to FIG. 2 and FIG. 3, a carrier board 80 in which a seed layer 84 including a first metal is disposed on at least one surface thereof may be prepared, and a conductive layer 92 including a second metal may be formed on the seed layer 84. The carrier board 80 may be a copper clad laminate (CCL) including an insulating board 81 and the seed layer 84. The first metal and the second metal may be metals having different etching conditions, the first metal may include copper (Cu), and the second metal may include nickel (Ni).

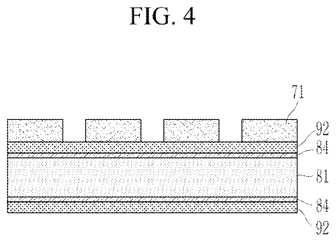

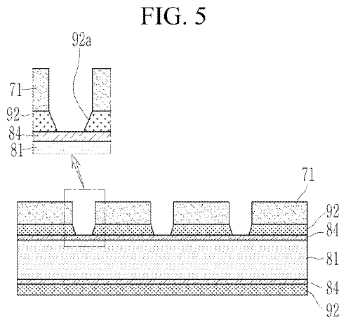

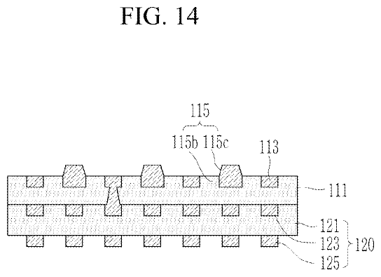

Referring to FIG. 4 and FIG. 5, a first plating resist 71 is applied on the conductive layer 92, and the first plating resist 71 is patterned to partially expose the conductive layer 92. The exposed portion of the conductive layer 92 may be removed by etching. The first plating resist 71 may be formed as a plating resist pattern removed by exposing and developing only a portion where the bump 115 of FIG. 14 will be formed.

The seed layer 84 may be partially exposed by etching the conductive layer 92 to form an opening 92a. In this case, a degree of etching of the conductive layer 92 may become weaker as the conductive layer 92 approaches the seed layer 84. Therefore, as the opening 92a of the conductive layer 92 approaches the seed layer 84, a width, a diameter, or a cross-sectional area of the opening 92a may gradually decrease.

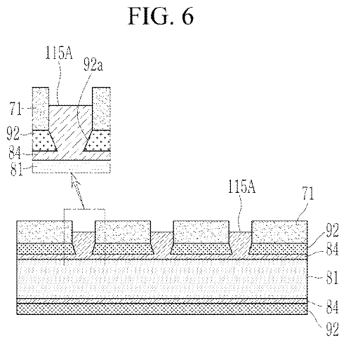

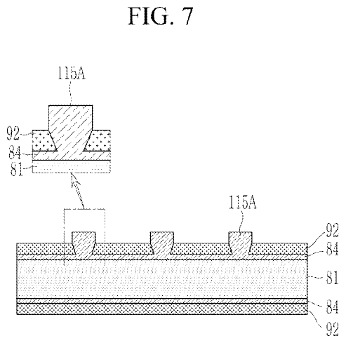

Referring to FIG. 6 and FIG. 7, a bump layer 115A is formed by plating a first metal on the exposed portion of the seed layer 84, and the first plating resist 71 is removed. The bump layer 115A may be made of the same metal material as that of the seed layer 84 to be integrally connected to the seed layer 84, and may be stacked along open portions of the conductive layer 92 and the first plating resist 71. In a height measured in a direction perpendicular to one surface of the carrier board 80 in which the seed layer 84 is formed, the bump layer 115A may be formed higher than the conductive layer 92, and may be formed lower than the first plating resist 71. Therefore, if the first plating resist 71 is removed, the metal bump layer 115A may be disposed to protrude above the conductive layer 92.

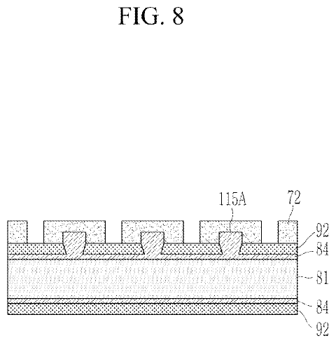

Referring to FIG. 8, a second plating resist 72 is applied on the conductive layer 92, and the applied second plating resist is patterned to partially expose the conductive layer 92. The second plating resist 72 may be formed to cover the bump layer 115A, and the exposed portion of the conductive layer 92 may have a different planar position from the bump layer 115A.

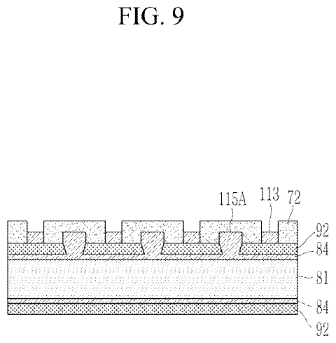

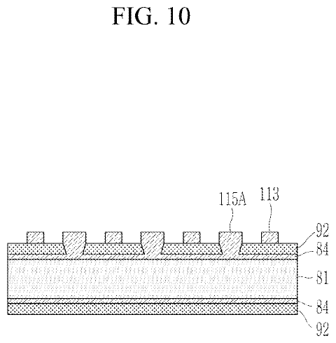

Referring to FIG. 9 and FIG. 10, a first metal is plated on the exposed portion of the conductive layer 92 to form the first wire layer 113, and the second plating resist 72 is removed. The first wire layer 113 may have a different planar position from the metal bump layer 115A, and may be formed partially at the same height as the metal bump layer 115A. However, because the first wire layer 113 and the metal bump layer 115A are formed by two independent processes, the height of the first wire layer 113 may be different from (e.g., less than or greater than) the height of the metal bump layer 115A with reference to the upper surface of the conductive layer 92, although not shown in the drawings. Additionally, because the conductive layer 92 includes a second metal, the conductive layer 92 may be distinguished from the first wire layer 113 including the first metal by forming a boundary with the first wire layer 113. If the second plating resist 72 is removed, the first wire layer 113 and the bump layer 115A may be disposed to protrude above the conductive layer 92.

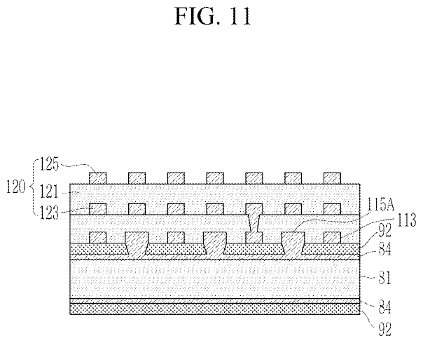

Referring to FIG. 11, the build-up structure 120 including the build-up insulating layer and the build-up wire layer is formed above the bump layer 115A and the first wire layer 113. Although not shown, a build-up via layer may be formed in the build-up insulating layer to connect the build-up wire layer to the first wire layer 113. Because the build-up structure 120 is laminated in a direction from the bottom to the top according to the view shown in FIG. 11, the build-up via layer may have a tapered shaped having a size increasing from the bottom to the top according to the view shown in FIG. 11. Each of the build-up insulating layer and the build-up wire layer may be formed to have a plurality of layers. In this case, the outermost wire layer 125 may be disposed to protrude on the outermost insulating layer 121.

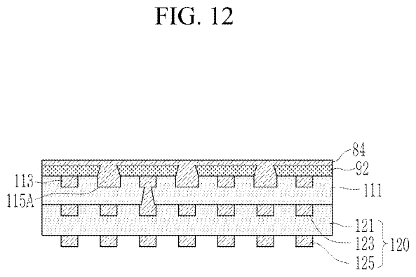

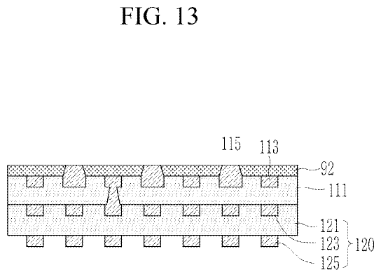

Referring to FIG. 12 and FIG. 13, the seed layer 84 and the insulating board 81 of the carrier board 80 are separated, and the seed layer 84 is etched to be removed. The seed layer 84 may be removed by a thickness of the seed layer 84 through soft etching. If the seed layer 84 is removed, bump layers 115A are separated from each other to form a plurality of bumps 115, and the conductive layer 92 may be maintained as is.

Referring to FIG. 14 and FIG. 1. the conductive layer 92 is removed by etching, and the first solder resist layer 131 and the second solder resist layer 132 are respectively formed on the first insulating layer 111 and the outermost insulating layer 121. Because the conductive layer 92 includes the second metal, the bump 115 and the first wire layer 113 respectively including the first metal having a different etching condition may be maintained even if the conductive layer 92 is etched. A portion buried in the first insulating layer 111 among portions of the bump 115 may become the base portion 115b, and a portion buried in the conductive layer 92 may become the protrusion portion 115c. The protrusion portion 115c may be formed to have the largest width at a surface height of the insulating layer 111 and the smallest width at an outermost upper end thereof along a protrusion direction to match a shape of the opening 92a of the conductive layer 92.

The first solder resist layer 131 may be formed on the first insulating layer 111 in a state in which the bump 115 is penetrated. The second solder resist layer 132 may be formed on the outermost insulating layer 121 in a state in which a portion of the outermost wire layer 125 is exposed.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A circuit board comprising:
a first insulating layer that has a first surface and a second surface opposing each other;
a first wire layer that is buried within the first insulating layer; and
a bump that includes a base portion disposed laterally to the first wire layer to be buried within the first insulating layer and a protrusion portion integrally extending and protruding from the base portion and having a width at an upper end thereof less than a width of the protrusion portion at a height of the first surface.

2. The circuit board of claim 1, wherein in the protrusion portion, the width at the height of the first surface is the largest and a width at the upper end of the protrusion portion is the smallest.

3. The circuit board of claim 1, wherein the width of the protrusion portion increases in a direction away from the first surface.

4. The circuit board of claim 1, wherein in a height measured in a direction perpendicular to the first surface, the base portion and the first wire layer have portions disposed at the same height as each other.

5. The circuit board of claim 1, wherein the base portion and the protrusion portion have the same width at the height of the first surface.

6. The circuit board of claim 1, further comprising a first solder resist layer disposed on the first surface and configured to cover the first wire layer.

7. The circuit board of claim 6, wherein the bump is disposed to penetrate the first solder resist layer.

8. The circuit board of claim 7, wherein the bump protrudes from the first solder resist layer.

9. The circuit board of claim 6, wherein the protrusion portion is disposed to contact the first solder resist layer.

10. The circuit board of claim 6, wherein the first solder resist layer is disposed to surround a portion of a side surface of the protrusion portion.

11. The circuit board of claim 1, wherein the bump includes copper (Cu).

12. The circuit board of claim 1, further comprising a build-up structure disposed on the second surface of the first insulating layer and including a plurality of build-up insulating layers and a plurality of build-up wire layers.

13. The circuit board of claim 12, further comprising a second solder resist layer disposed on an outermost insulating layer disposed at an outermost side of the plurality of build-up insulating layers.

14. A method of fabricating a circuit board, comprising:
forming a conductive layer including a second metal on a seed layer including a first metal;
forming a bump layer on the seed layer exposed by patterning the conductive layer;
forming an insulating layer and a wire layer above the conductive layer;
removing the seed layer to form a bump from the bump layer;
removing the conductive layer to protrude the bump from the insulating layer; and
forming a solder resist layer on one surface of the insulating layer where the bump protrudes.

15. The method of claim 14, wherein the first metal includes copper (Cu) and the second metal includes nickel (Ni).

16. The method of claim 14, wherein the forming of the bump layer comprises:
applying a plating resist on the conductive layer and patterning the applied plating resist to expose the conductive layer;
removing the exposed portion of the conductive layer to expose the seed layer; and
forming the bump layer by plating the first metal on the exposed seed layer.

17. The method of claim 14, wherein the bump is formed to have the largest width at a surface height of the insulating layer and the smallest width at an outermost upper end thereof along a direction protruding from the insulating layer.

18. The method of claim 14, further comprising forming a build-up structure on another surface of the insulating layer,
wherein the build-up structure includes a plurality of build-up insulating layers and a plurality of build-up wire layers.

19. The method of claim 18, wherein the conductive layer and the seed layer are formed on an insulating board which is removed after forming the build-up structure.

20. The method of claim 14, wherein the bump protrudes from the solder resist layer.
